(19) United States
(12) Patent Application Publication
(10) Pub. No.: US 2006/0066178 A1
(43) Pub. Date: Mar. 30, 2006

(54) Piezoelectric actuator with strain-reducing structures

(76) Inventors: Friederike Lindner, Gerlingen (DE); Volker Knoblauch, Stuttgart (DE); Gaetan Deromelaere, Kornwestheim (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 11/212,590

(22) Filed: Aug. 29, 2005

(30) Foreign Application Priority Data
Sep. 29, 2004 (DE) 10 2004 047 105.3

(51) Int. Cl. H01L 41/083

(52) U.S. Cl. 310/328

(57) ABSTRACT

A piezoelectric actuator has stacked ceramic layers of a piezoelectric material and electrodes situated between the layers to form a piezoelectric stack and having at least one structure that reduces the mechanical strain occurring in the piezoelectric stack. The strain reducing structure is comprised of a strain-reducing layer equipped with recesses and is typically situated between the ceramic layers. In particular, the recesses of the strain-reducing layer are situated in an outer region of the layer and is comprised of a notch which significantly reduce the mechanical strains inside the actuator.

### CROSS-REFERENCE TO RELATED APPLICATIONS

This application is based on German Patent Application 10 2004 047 105.3 filed Sep. 29, 2004, upon which priority is claimed.

### BACKGROUND OF THE INVENTION

1. Field of the Invention

The present invention is directed to an improved piezoelectric actuator of the type having stacked layers of piezoelectric material.

2. Description of the Prior Art

Piezoelectric actuators are used in numerous industrial applications, known examples of which include, among others, actuators for actuating a valve closure member of a fuel injection valve, for actuating hydraulic valves, or for driving micropumps.

Typically, the piezoelectric actuators, for example of the kind shown in FIG. 3 of DE-198 02 302 A1, are comprised of a number of stacked layers of a piezoelectric material, so-called piezoelectric elements, and electrodes situated between the piezoelectric layers. The electrodes are arranged in an interdigital comb structure, i.e. a first and a second external electrode contact the respective electrodes inside the piezoelectric stack in an alternating fashion. The electrodes inside the piezoelectric stack are called internal electrodes for short and are oriented perpendicular to the two external electrodes. Both layer surfaces of each piezoelectric layer are thus attached to a respective internal electrode and the first or second external electrode can apply an electrical voltage. When the voltage is applied, each of the stacked wafer-like piezoelectric elements expands in the direction of the electrical field produced between the internal electrodes. The large number of stacked piezoelectric elements makes it possible to achieve a relatively large stroke in the stack direction of the entire arrangement with a simultaneously low triggering voltage.

In these actuators with the interdigital electrode structure, because of the attachment of the stacked piezoelectric elements and internal electrodes with the two external electrodes, the piezoelectrically generated expansion mainly occurs in only the central region where the internal electrodes completely overlap one another. In the edge zones where the internal electrodes do not overlap directly with the respective electrodes closest to them, there is a region with an altered field strength, which also results in the occurrence of tensile stresses. As a result of this mechanical strain, actuators of this kind frequently develop cracks.

In order to prevent the this kind of crack development, the application cited above has proposed providing the actuator with a total of four external electrodes; an external electrode is situated on each side of the piezoelectric stack and the respective pairs of external electrodes are electrically connected to a plus pole and a minus pole. The critical regions in which the internal electrodes contact the external electrodes are thus distributed over more side surfaces of the piezoelectric stack, thus permitting these regions to be spaced further apart from one another in the stacking direction. This measure makes it possible to reduce the tensile stresses in the piezoelectric stack and thus reduce the propensity toward crack development.

One disadvantage of the arrangement for crack prevention known from the prior art is that it requires a total of four external electrodes instead of two. In addition, the structure of the piezoelectric stack is more complex since care must be taken to follow the cyclical sequence when producing the contacts between the internal electrodes and the four different external electrodes. Moreover, it is not possible to respond to the presence of a more powerful mechanical strain by expanding to more than four external electrodes since a piezoelectric stack with square piezoelectric wafers has exactly four side surfaces. The potential for increasing the distance between the contact regions of the internal and external electrodes has therefore been exhausted.

### OBJECT AND SUMMARY OF THE INVENTION

The piezoelectric actuator according to the present invention has the advantage over the prior art of significantly reducing undesirable tensile stresses in the edge regions of the piezoelectric elements of the piezoelectric stack without having to provide an external electrode on all four side surfaces. Simple means achieve a reduction in the mechanical strains inside the piezoelectric actuator and therefore a minimization of damage to the material such as crack development or other performance-reducing failures. The piezoelectric actuator according to the present invention also offers the possibility of intensifying the strain-reducing action as needed. Finally, it should be emphasized here that the device according to the present invention is not intended to work around the effects of crack development, but instead, thanks to the strain relaxation it advantageously offers, cracks do not even develop in the first place.

Advantageous modifications of the piezoelectric actuator are possible by means of the measures disclosed and described in the specification.

### BRIEF DESCRIPTION OF THE DRAWINGS

The invention will be better understood and further objects and advantages thereof will become more apparent from the ensuing detailed description of preferred embodiments taken in conjunction with the drawings, in which:

FIGS. 1a, 1b show possible contacting schemes for the electrodes,

FIG. 2 shows a section through a piezoelectric stack with an interdigital electrode structure,

FIG. 3 shows a course of field lines in piezoelectric layers in order to indicate the active and semi-active regions,

FIG. 4 shows a strain-reducing structure, and

FIG. 5 shows a piezoelectric actuator with strain-reducing layers.

### DESCRIPTION OF THE PREFERRED EMBODIMENTS

As has already been mentioned above, piezoelectric actuators are usually comprised of a number of stacked layers of a piezoelectric material. Electrodes are placed between the layers and contact a plus pole and a minus pole in an alternating sequence.

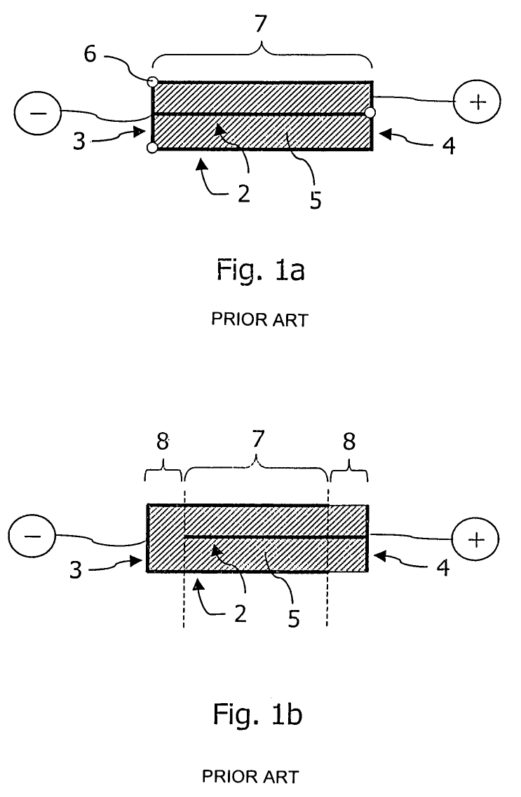

FIGS. 1a and 1b show the two possible contacting schemes. So-called internal electrodes 2, which extend parallel to the piezoelectric layers 5, are contacted on alternating sides by a first external electrode 3 or a second external electrode 4. The first external electrode 3 here is connected to a minus pole and the second external electrode 4 is connected to a plus pole. The embodiment depicted in FIG. 1a has full-surface internal electrodes 2, i.e. the internal electrodes 2 extend all the way from the first external electrode 3 to the second external electrode 4. But since an internal electrode 2 is only permitted to electrically contact one external electrode 4, insulators 6 are provided at corresponding points in which no contact should occur. The embodiment with the full-surface internal electrodes 2 advantageously has only so-called active regions 7 with a constant field strength because every region in the piezoelectric element is always situated between two oppositely charged internal electrodes 2. Because of the constant field strength in the entire region of the piezoelectric element, the mechanical expansion is also constant. But the need to provide an insulator 6 for each internal electrode 2 on alternating sides in relation to the first 3 or second external electrode 4 disadvantageously complicates this design. This is why the second possible contacting scheme between the internal electrodes 2 and the external electrodes 3, 4, namely the interdigital electrode structure, has become the established norm.

FIG. 1b shows the arrangement in an interdigital electrode structure. The internal electrodes 2 here are shorter than the full-surface internal electrodes 2 from FIG. 1a and therefore do not require insulators 6 in the structure. However, two adjacent internal electrodes 2 no longer completely overlap each other. Instead, in addition to the central, active region 7, the piezoelectric layers 5 also have so-called semi-active regions 8 produced by the offset internal electrodes 2.

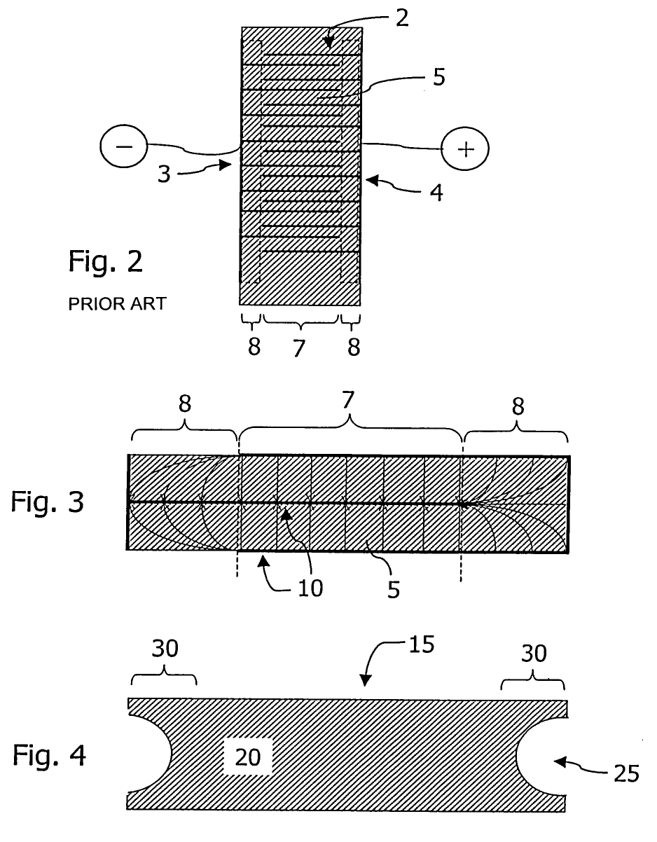

FIG. 2 shows a section through a typical structure of a piezoelectric stack comprised of a number of piezoelectric layers 5 placed one on top of another. The first 3 or second external electrode 4 electrically contact the internal electrodes 2 in the known way on alternating sides to a minus pole or a plus pole. In the active region 7, the internal electrodes 2 overlap completely, resulting in a constant electrical field. In the semi-active regions 8, however, a heterogeneous electrical field is generated due to the offset internal electrodes 2.

For illustrative purposes, FIG. 3 shows the field lines of the electrical fields inside the piezoelectric layers 5. Since the discussion below will center exclusively on the internal electrodes 2, these internal electrodes 2 will simply be referred to as electrodes 10 since there is no risk of confusion. In the central, active region 7 of the layers 5, two oppositely charged electrodes 10 are always spaced the same distance apart, thus generating a homogeneous field and homogeneous distribution of the expansion. In the semi-active regions 8, however, the expansions are not homogeneous due to the reduced, non-constant field strengths and are also absolutely reduced in comparison to the active region 7. These expansion differences result in powerful mechanical strains in the edge regions of the actuator.

According to the present invention, the piezoelectric actuator is provided with at least one structure that reduces mechanical strains occurring in the piezoelectric stack. FIG. 4 shows a possible strain-reducing structure 15. The structure 15 can, for example, be comprised of a strain-reducing layer 20 with recesses 25. The recess 25 is advantageously provided in at least one outer region 30 of the strain-reducing layer 20. The recess 25 of the layer 20 can be comprised of a notch, i.e. an indentation, in a surface of the layer 20. In an optimal embodiment, the cross section of the notch is the shape of a semicircle or another symmetrical figure. Otherwise, the structure 15 can be comprised of a piezoelectrically active or inactive material and the recesses 25 can be formed before or after the sintering of the layer 20.

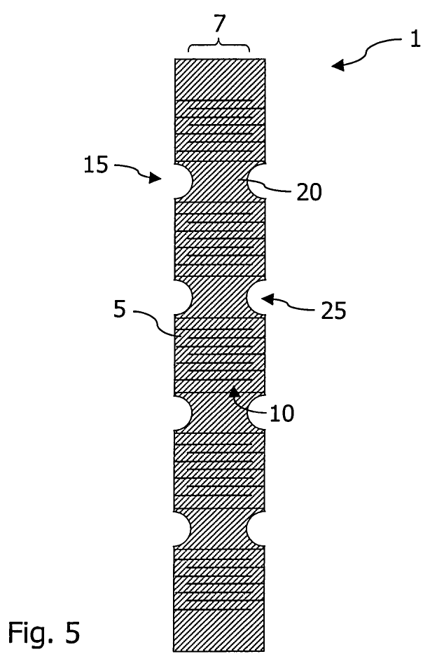

The strain-reducing layer 20 with recesses 25, as depicted in FIG. 5, is advantageously situated between the piezoelectric layers 5. The piezoelectric actuator 1 in this example has four strain-reducing layers 20 with recesses 25, which are distributed evenly throughout the piezoelectric stack. Despite the interdigital electrode structure used, the recesses 25 now permit the active region 7 to expand freely and an excessive build-up of strain is prevented from occurring. The precise number or geometric size of the recesses 25 depend on the actuator type and can be varied as needed. If certain actuator types are associated with more powerful mechanical strains, then additional strain-reducing layers 20 can be integrated into the piezoelectric stack and/or the recesses 25 can be enlarged.

On the whole, the integration of strain-reducing layers 20 achieves a significant mechanical relaxation, which permits the actuator to function in a generally strain-free state. This has a direct, advantageous effect on the reliability of the actuator.

The foregoing relates to preferred exemplary embodiments of the invention, it being understood that other variants and embodiments thereof are possible within the spirit and scope of the invention, the latter being defined by the appended claims.

We claim:

1. A piezoelectric actuator (1) comprising
stacked layers (5) of a piezoelectric material
electrodes (10) situated between the stacked layers (5) to form a piezoelectric stack, and
at least one structure (15) that reduces the mechanical strains occurring in the piezoelectric stack contained within the piezoelectric stack.

2. The piezoelectric actuator (1) according to claim 1, wherein the structure (15) is comprised of a strain-reducing layer (20) equipped with recesses (25).

3. The piezoelectric actuator (1) according to claim 2, wherein the strain-reducing layer (20) is situated between the layers (5) of a piezoelectric material.

4. The piezoelectric actuator (1) according to claim 2, wherein the recess (25) of the strain-reducing layer (20) is situated in at least one outer region (30) of the layer (20).

5. The piezoelectric actuator (1) according to claim 3, wherein the recess (25) of the strain-reducing layer (20) is situated in at least one outer region (30) of the layer (20).

6. The piezoelectric actuator (1) according to claim 4, wherein the recess (25) in the layer (20) is a notch.

7. The piezoelectric actuator (1) according to claim 5, wherein the recess (25) in the layer (20) is a notch.

8. The piezoelectric actuator (1) according to claim 6, wherein the notch in the cross section of the layer (20) is the shape of a semicircle or another symmetrical figure.

9. The piezoelectric actuator (1) according to claim 7, wherein the notch in the cross section of the layer (20) is the shape of a semicircle or another symmetrical figure.

10. The piezoelectric actuator (1) according to claim 1, wherein the structure (15) is comprised of a piezoelectrically active or inactive material.

11. The piezoelectric actuator (1) according to claim 2, wherein the structure (15) is comprised of a piezoelectrically active or inactive material.

12. The piezoelectric actuator (1) according to claim 3, wherein the structure (15) is comprised of a piezoelectrically active or inactive material.

13. The piezoelectric actuator (1) according to claim 4, wherein the structure (15) is comprised of a piezoelectrically active or inactive material.

14. The piezoelectric actuator (1) according to claim 6, wherein the structure (15) is comprised of a piezoelectrically active or inactive material.

15. The piezoelectric actuator (1) according to claim 8, wherein the structure (15) is comprised of a piezoelectrically active or inactive material.

16. The piezoelectric actuator (1) according to claim 2, wherein the layer (20) is formed of a sintered material, and wherein the recesses (25) are formed before or after the sintering of the layer (20).

17. The piezoelectric actuator (1) according to claim 3, wherein the layer (20) is formed of a sintered material, and wherein the recesses (25) are formed before or after the sintering of the layer (20).

18. The piezoelectric actuator (1) according to claim 4, wherein the layer (20) is formed of a sintered material, and wherein the recesses (25) are formed before or after the sintering of the layer (20).

19. The piezoelectric actuator (1) according to claim 6, wherein the layer (20) is formed of a sintered material, and wherein the recesses (25) are formed before or after the sintering of the layer (20).

20. The piezoelectric actuator (1) according to claim 8, wherein the layer (20) is formed of a sintered material, and wherein the recesses (25) are formed before or after the sintering of the layer (20).
